(19) United States
(12) Patent Application Publication
(10) Pub. No.: US 2025/0324587 A1
(43) Pub. Date: Oct. 16, 2025

(54) SEMICONDUCTOR STRUCTURE AND METHOD FOR FORMING THE SAME

(71) Applicant: Winbond Electronics Corp., Taichung City (TW)

(72) Inventors: Meng-Hsien TSAI, Taichung City (TW); Cheng-Shuai LI, Taichung City (TW); Kao-Tsair TSAI, Taichung City (TW)

(21) Appl. No.: 18/825,062

(22) Filed: Sep. 5, 2024

(30) Foreign Application Priority Data
Apr. 12, 2024 (TW) 113113755

(51) Int. Cl. H10B 41/30; H01L 21/28; H01L 29/66; H01L 29/788

(52) U.S. Cl. CPC H10B 41/30; H10D 30/0411; H10D 30/683; H10D 64/035

(57) ABSTRACT

A method for forming a semiconductor structure is provided. The method includes providing a substrate with active regions, forming a first gate layer on the active regions of the substrate, and conformally forming an inter-gate dielectric layer on the substrate and the first gate layer. The inter-gate dielectric layer forms a first opening between the first gate layer. The method includes forming a second gate layer on the inter-gate dielectric layer, wherein the second gate layer is filled in the first opening, forming a patterned photoresist layer on the second gate layer, and using the patterned photoresist layer as a mask and patterning the second gate layer to form a second opening. The second opening is directly over the first opening. The method further includes patterning the second gate layer, the inter-gate dielectric layer, and the first gate layer to form a word line structure on the substrate.

### CROSS REFERENCE TO RELATED APPLICATIONS

This Application claims priority of Taiwan Patent Application No. 113113755 filed on Apr. 12, 2024, the entirety of which is incorporated by reference herein.

### BACKGROUND OF THE INVENTION

### Field of the Invention

The present disclosure relates to a method for forming a semiconductor structure, and in particular to a method for forming a flash memory structure.

### Description of the Related Art

Memory components are usually categorized into two main types, i.e., volatile memory and non-volatile memory. Volatile memory refers to memory that relies on a continuous power supply to maintain and store the data within the memory. Non-volatile memory may still store the data within the memory even if the system power is interrupted. Non-volatile memory includes one-time programmable devices (e.g., electronically programmable read-only memory (EPROM)) or re-programmable devices (e.g., electronically-erasable programmable read-only memory (EEPROM)). Flash memory (a type of non-volatile memory) may quickly perform writing and erasing operations.

In order to increase the component density and improve the overall performance of flash memory devices, the current technology used in manufacturing flash memory devices keeps striving for scaling-down the dimensions of the component. However, many challenges arise when the device dimensions keep reducing. For example, due to differences in environmental structures, during the etching process of the word line structure for patterning the memory device, incomplete etching of the conductor layer may result in short circuits between the word lines. In addition, the over-etching of a conductor layer may damage sidewalls of the word line structure, which may cause reliability problems for the memory device. Therefore, the industry still needs to improve the method of manufacturing flash memory devices to achieve the desired goal of maintaining the memory device yield and manufacturing progress.

### BRIEF SUMMARY OF THE INVENTION

An embodiment of the present disclosure provides a method for forming a semiconductor structure, including providing a substrate. The substrate includes a plurality of active regions. The method includes forming a first gate layer on the active regions of the substrate, and conformally forming an inter-gate dielectric layer on the substrate and the first gate layer. The inter-gate dielectric layer forms a first opening between the first gate layer. The method includes forming a second gate layer on the inter-gate dielectric layer, wherein the second gate layer is filled into the first opening, and forming a patterned photoresist layer on the second gate layer. The method further includes using the patterned photoresist layer as a mask, patterning the second gate layer to form a second opening, wherein the second opening is directly over the first opening, and patterning the second gate layer, the inter-gate dielectric layer, and the first gate layer to form a word line structure on the substrate.

The substrate includes a plurality of isolation structures between the active regions. The top surface of the isolation structures is higher than the top surface of the active regions and lower than the top surface of the first gate layer. There is a liner layer between the substrate and the isolation structures.

The word line structure has a plurality of protrusions correspondingly formed over the active regions, and the width of each of the protrusions is less than or equal to the width of each of the active regions.

The width of the second opening is greater than the width of the first opening, the depth of the first opening is greater than the depth of the second opening.

The patterning of the second gate layer, the inter-gate dielectric layer, and the first gate layer forms the word line structure further includes forming a mask layer on the second gate layer, the mask layer is filled the second opening, and performing an etching process to sequentially pattern the second gate layer, the inter-gate dielectric layer, and the first gate layer to form the word line structure.

The etching process includes an anisotropic etching process, The inter-gate dielectric layer includes an oxide/nitride/oxide layer, The material of the first gate layer and the second gate layer includes polycrystalline silicon.

The embodiment of the present disclosure provides a semiconductor structure, including a substrate. The substrate includes a plurality of active regions and a plurality of isolation structures disposed in an interleaving configuration. The top surface of the isolation structures is higher than the top surface of the active regions. The semiconductor structure further includes a word line structure. The word line structure includes a floating gate formed on each of the active regions of the substrate, an inter-gate dielectric layer conformally covering the floating gate and the substrate, and a control gate formed over the floating gate and separated from the floating gate by the inter-gate dielectric layer. The word line structure has a plurality of protrusions correspondingly formed over the active regions.

The top surface of the isolation structures of the substrate is lower than the top surface of the floating gate of the word line structure, the width of each of the protrusions is less than or equal to the width of each of the active regions of the substrate.

The word line structure extends along a first direction, the active regions extend along a second direction, the first direction intersects the second direction, and the protrusions extend along the second direction and are aligned in the first direction.

In a cross-sectional view in the first direction, the word line structure has a crown shape, and the word line structure has a rectangular shape.

The spacing between the protrusions is greater than the top width of each of the isolation structures of the substrate.

There is a liner layer between the substrate and the isolation structures.

The material of the liner layer includes silicon oxide, the inter-gate dielectric layer includes an oxide/nitride/oxide layer, the material of the floating gate and the control gate includes polycrystalline silicon.

### BRIEF DESCRIPTION OF THE DRAWINGS

FIGS. 1, 2, 3, 4, and 5 illustrate perspective views of intermediate stages for forming the semiconductor structure, in accordance with the embodiments of the present disclosure;

FIGS. 6 and 7 illustrate cross-sectional views of the semiconductor structure, in accordance with the embodiments of the present disclosure.

### DETAILED DESCRIPTION OF THE INVENTION

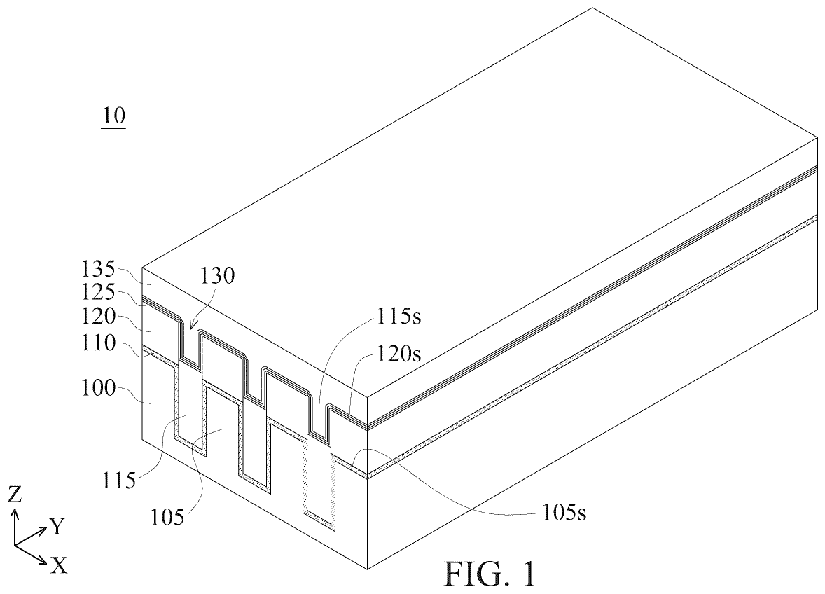

FIG. 1 illustrates a perspective view of the semiconductor structure 10, in accordance with the embodiments of the present disclosure. The substrate 100 includes a plurality of active regions 105, a liner layer 110, and a plurality of isolation structures 115. Performing an appropriate etching process on the substrate 100 to etch out the isolated trenches and define the plurality of active regions 105. The liner layer 110 is subsequently formed to cover the active regions 105 and the sidewalls and the bottom surfaces of the isolated trenches. The liner layer 110 on the top surface of the active regions may serve as a tunnel oxide layer for the memory device, the liner layer 110 is formed from silicon oxide.

Next, a first gate layer 120 may be formed on the substrate 100. The first gate layer 120 may subsequently serve as a floating gate for the semiconductor structure, a conductor layer (not shown) may be formed on the substrate 100 by deposition processes such as chemical vapor deposition, other suitable processes, or a combination thereof. A suitable etching process is performed on the conductor layer to expose the isolated trench, thereby forming the first gate layer 120. More specifically, the first gate layer 120 is formed on each of the active regions 105 of the substrate 100, the material of the first gate layer 120 may include doped polycrystalline silicon, undoped polycrystalline silicon, metal, polycrystalline metal silicide (polycide), or a combination thereof.

Subsequently, a spin-on coating process, a chemical vapor deposition process, an atomic layer deposition process, other suitable process, or a combination thereof may be performed to deposit the insulating material layer (not shown), and a suitable etching process is performed to form the isolation structures 115. The isolation structures 115 are between the active regions 105, the active regions 105 and the isolation structures 115 are disposed in an interleaving configuration. The top surface 115s of the isolation structures 115 is higher than the top surface 105s of the active regions 105, and the top surface 115s of the isolation structures 115 is lower than the top surface 120s of the first gate layer 120, which effectively reduces leakage currents that may be generated between the different active regions 105. The liner layer 110 is between the substrate 100 and the isolation structures 115.

Referring to FIG. 1, the inter-gate dielectric layer 125 is conformally formed on the substrate 100 and the first gate layer 120. The inter-gate dielectric layer 125 conformally covers the sidewalls of the first gate layer 120 and the top surface 120s of the first gate layer 120, and covers the top surface 115s of the isolation structures 115. Since the first gate layer 120 is formed on each of the active regions 105, the inter-gate dielectric layer 125 forms a first opening 130 between the first gate layer 120. The inter-gate dielectric layer 125 includes a composite layer formed of oxide/nitride/oxide (ONO), but the present disclosure is not limited to it, and the composite layer may also be a film of five or more layers.

Referring to FIG. 1, a second gate layer 135 is formed on the inter-gate dielectric layer 125 and over the first gate layer 120, and the second gate layer 135 is filled into the first opening 130. The second gate layer 135 may subsequently serve as a control gate for the semiconductor structure, the second gate layer 135 may be formed by deposition processes such as chemical vapor deposition, other suitable processes, or a combination thereof, similar to the first gate layer 120, the material of the second gate layer 135 may include doped polycrystalline silicon, undoped polycrystalline silicon, metal, polycrystalline metal silicide (polycide), or a combination thereof.

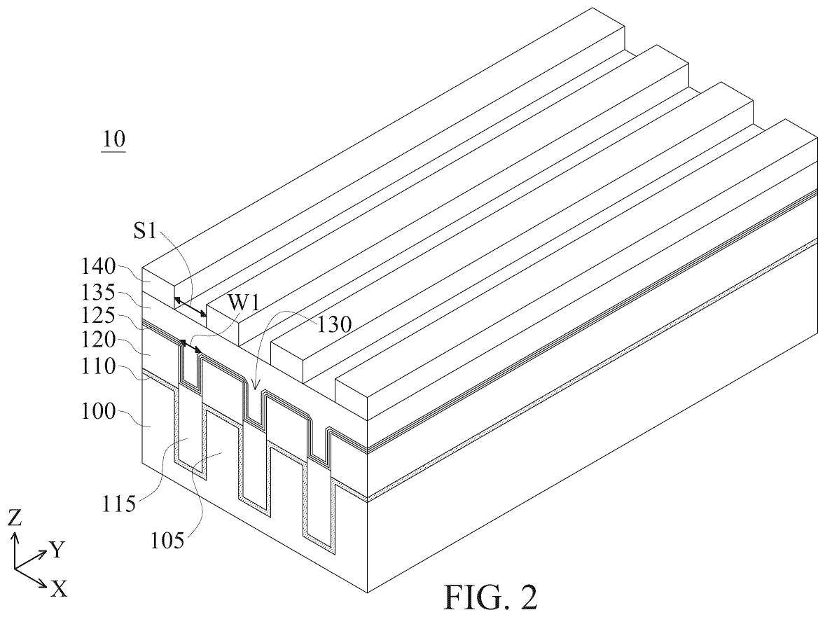

FIG. 2 illustrates a perspective view of forming a patterned photoresist layer 140 on the semiconductor structure 10. After forming the second gate layer 135 on the inter-gate dielectric layer 125, the patterned photoresist layer 140 is formed on the second gate layer 135. The patterned photoresist layer 140 is formed only over the first gate layer 120. In other words, the patterned photoresist layer 140 partially overlaps with the active regions 105, and the spacing S1 of the patterned photoresist layer 140 is greater than the width W1 of the first opening 130.

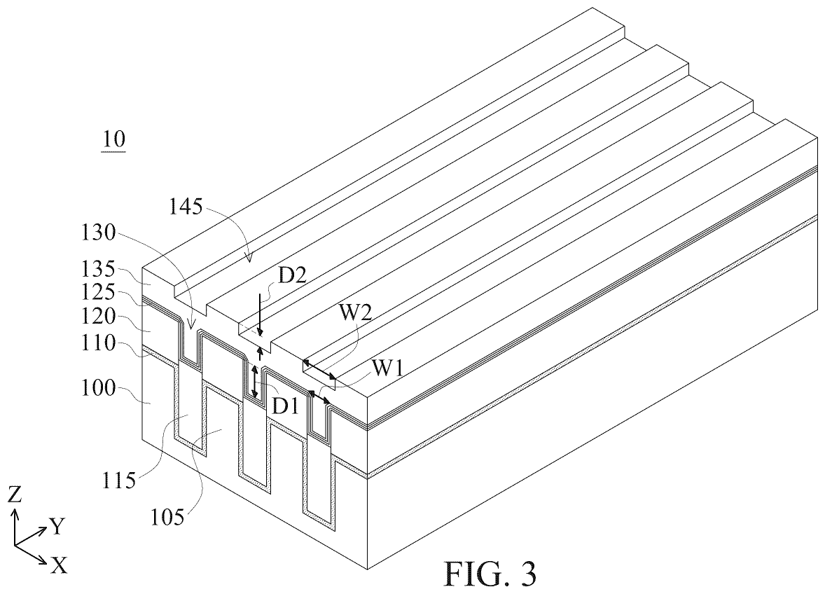

FIG. 3 illustrates a perspective view of the semiconductor structure 10 after etching the second gate layer 135. After forming the patterned photoresist layer 140, the patterned photoresist layer 140 is used as a mask to pattern the second gate layer 135 to form a second opening 145, and the second opening 145 is located directly over the first opening 130. Using the patterned photoresist layer 140 as a mask, the second gate layer 135 is pre-etched to form the second opening 145 directly over the first opening 130 (i.e., the portion of the second gate layer 135 directly over the first opening 130 is pre-etched). Accordingly, the etching process of the word line structure subsequently enables to completely remove the portion of the second gate layer 135 filled into the first opening 130, and avoiding the problem of short circuits of the word line of the memory device caused by incomplete etching. The width W2 of the second opening 145 is greater than the width W1 of the first opening 130. The depth D1 of the first opening 130 is greater than the depth D2 of the second opening 145. Depending on the design, the ratio or relative relationship between the width of the first opening 130 and the second opening 145 may be adjusted or modified, e.g., if the depth of the first opening 130 is deeper, the depth of the second opening 145 may be further deepened to ensure that the relevant film may be completely etched. After forming the second opening 145, the patterned photoresist layer 140 may be removed by a process such as an etching process, a strip process, an ashing process, or a combination thereof.

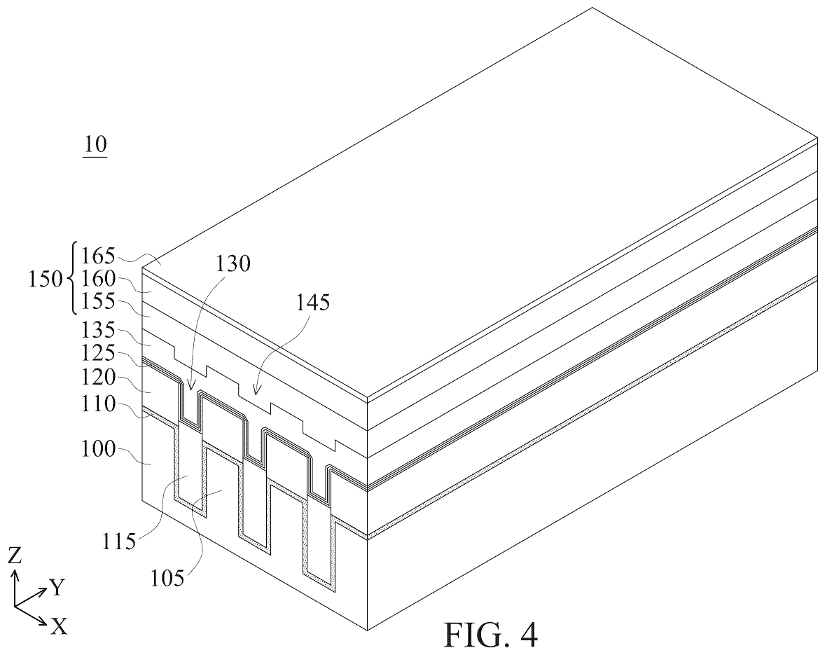

FIG. 4 illustrates a perspective view of forming a mask layer 150 on the semiconductor structure 10. The mask layer 150 is formed on the second gate layer 135 and is filled into the second opening 145. The mask layer 150 is subsequently patterned by the relevant photolithography process to serve as a mask for patterning the second gate layer 135, the inter-gate dielectric layer 125, and the first gate layer 120, the mask layer 150 may further include an oxide layer 155, a mandrel layer 160, and a cap layer 165. A photoresist pattern (not shown) is first formed on the mask layer 150 by a photolithography process and an etching process, and then the photoresist pattern is transferred to the mask layer 150 on the second gate layer 135 by an etching process to form the mask for patterning the word line structure 170 (described in detail below), similar to the steps for forming the patterned photoresist layer 140, the photoresist pattern may be formed by a lithography process (e.g., photolithography or electron beam lithography) followed by an etching process, which will not be described herein again, the mask layer 150 may be formed by processes such as chemical vapor deposition (CVD), atomic layer deposition (ALD), or a combination thereof. The material of the oxide layer 155 may include an oxide formed with tetraethylorthosilicate (TEOS), the material of the mandrel layer 160 may include carbon, the material of the cap layer 165 may include silicon oxynitride (SiON), bottom anti-reflective coating (BARC), or a combination thereof.

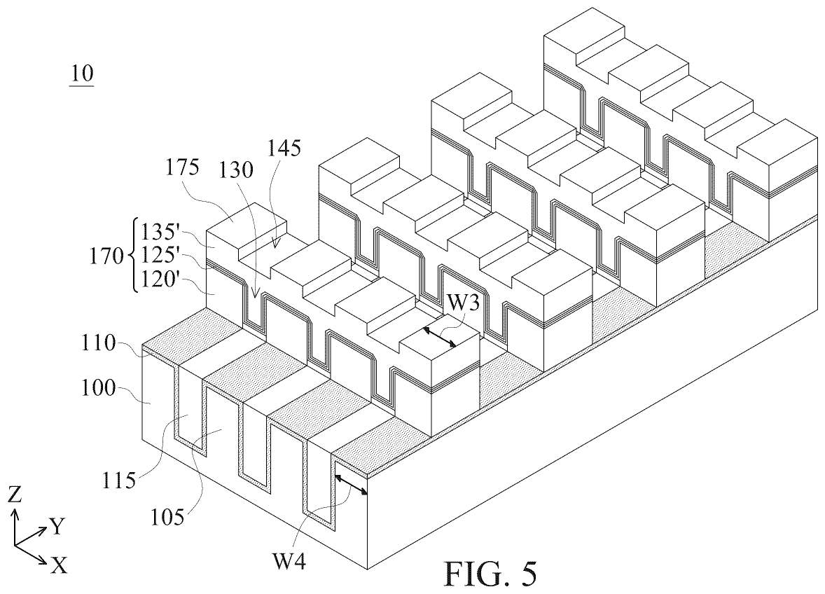

FIG. 5 illustrates a perspective view of forming a word line structure 170. After patterning the mask layer 150 (not shown), using the patterned mask layer 150 as a mask, an etching process is performed on the substrate 100 to sequentially pattern the second gate layer 135, the inter-gate dielectric layer 125, and the first gate layer 120 and to form the word line structure 170 on the substrate 100. The second gate layer 135 is patterned first, and the inter-gate dielectric layer 125 serves as an etching stop layer for patterning the second gate layer 135 due to differences in etching selectivity, and then the inter-gate dielectric layer 125 and the first gate layer 120 continue to be etched sequentially in the same manner. The word line structure 170 includes a first gate layer 120′ (as the floating gate of the memory device), an inter-gate dielectric layer 125′, and a second gate layer 135′ (as the control gate of the memory device) in the third direction Z from bottom to top. The control gate (the second gate layer 135′) is formed over the floating gate (the first gate layer 120′) and is separated from the floating gate (the first gate layer 120′) by the inter-gate dielectric layer 125′. Due to the formation of the second opening 145, the word line structure 170 has a plurality of protrusions 175 correspondingly formed over the respective active regions 105. The width W3 of each of the protrusions 175 is less than or equal to the width W4 of each of the active regions 105.

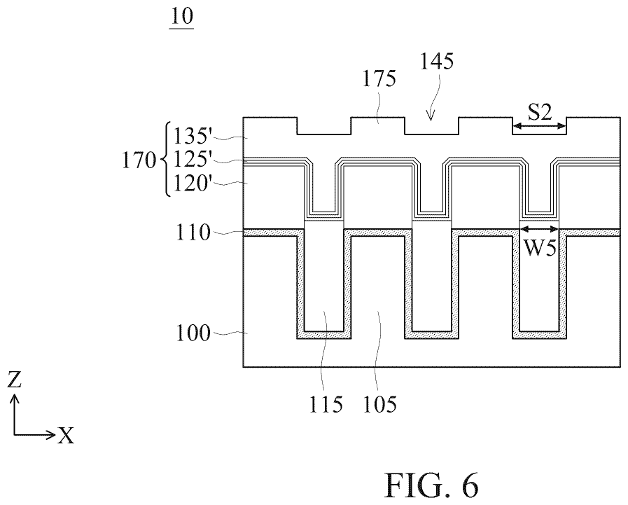

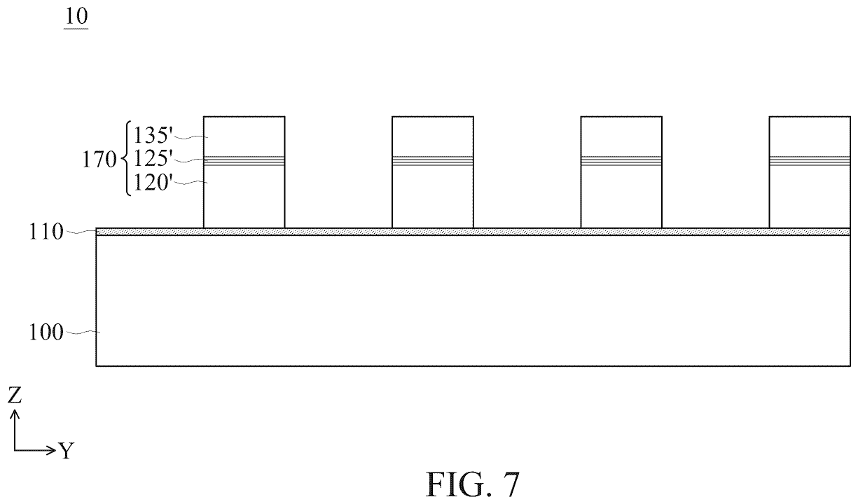

FIG. 6 illustrates a cross-sectional view of the semiconductor structure 10 in the first direction X (the plane of the first direction X-the third direction Z. FIG. 7 illustrates a cross-sectional view of the semiconductor structure 10 in the second direction Y (the plane of the second direction Y-the third direction Z. As shown in FIGS. 5 to 7, the word line structure 170 extends along the first direction X, the active regions 105 extend along the second direction Y, the first direction X intersects the second direction Y, and the first direction X, the second direction Y, and the third direction Z intersect each other. The protrusions 175 extend along the second direction Y and are aligned in the first direction X. As shown in FIG. 6, due to the formation of the second opening 145 and the protrusions 175, the word line structure 170 has a crown shape in the cross-section of the first direction X. As shown in FIG. 7, due to the formation of the second opening 145 that is capable of pre-etching a portion of the second gate layer 135, during the etching process of patterning the word line structure 170, there is no need to increase the intensity of the etching process (i.e., over etching) in order to minimize short circuits caused by incomplete etching. Therefore, the word line structure 170 may be ideally maintained to have a rectangular shape in the cross-sectional view in the second direction Y. The spacing S2 between the protrusions 175 is greater than the top width W5 of the respective isolation structures 115. After forming the word line structure 170, semiconductor processes such as various deposition, lithography, etching, etc. may be performed to form other related components of the memory device, which are not further described herein.

In summary, compared to the conventional forming process of the word line structure, the embodiment of the present disclosure effectively avoids the possibility of the second gate layer being adversely remained in the first opening by forming the second opening to pre-etch the second gate layer. Accordingly, the incomplete etching of the first gate layer, the inter-gate dielectric layer, and the second gate layer is reduced. In addition, short circuits of the word line structure is avoided and the occurrence of excessive damage to the sidewalls of the word line structure by the etching process is minimized, so as to maintain the memory device yield and manufacturing progress goals. Thus, the various embodiments described herein offer several advantages over the existing art. It will be understood that not all advantages have been necessarily discussed herein, no particular advantage is required for all embodiments, and other embodiments may offer different advantages.

One aspect of the present disclosure provides a method for forming a semiconductor structure, including providing a substrate. The substrate includes a plurality of active regions. The method includes forming a first gate layer on the active regions of the substrate, and conformally forming an inter-gate dielectric layer on the substrate and the first gate layer. The inter-gate dielectric layer forms a first opening between the first gate layer. The method includes forming a second gate layer on the inter-gate dielectric layer, wherein the second gate layer is filled into the first opening, and forming a patterned photoresist layer on the second gate layer. The method further includes using the patterned photoresist layer as a mask, patterning the second gate layer to form a second opening, wherein the second opening is directly over the first opening, and patterning the second gate layer, the inter-gate dielectric layer, and the first gate layer to form a word line structure on the substrate.

The substrate includes a plurality of isolation structures between the active regions. The top surface of the isolation structures is higher than the top surface of the active regions and lower than the top surface of the first gate layer. There is a liner layer between the substrate and the isolation structures.

The word line structure has a plurality of protrusions correspondingly formed over the active regions, and the width of each of the protrusions is less than or equal to the width of each of the active regions.

The width of the second opening is greater than the width of the first opening, the depth of the first opening is greater than the depth of the second opening.

The patterning of the second gate layer, the inter-gate dielectric layer, and the first gate layer to form the word line structure further includes forming a mask layer on the second gate layer, the mask layer is filled the second opening, and performing an etching process to sequentially pattern the second gate layer, the inter-gate dielectric layer, and the first gate layer to form the word line structure.

The etching process includes an anisotropic etching process, the inter-gate dielectric layer includes an oxide/nitride/oxide layer, the material of the first gate layer and the second gate layer includes polycrystalline silicon.

Another aspect of the present disclosure provides a semiconductor structure, including a substrate. The substrate includes a plurality of active regions and a plurality of isolation structures disposed in an interleaving configuration. The top surface of the isolation structures is higher than the top surface of the active regions. The semiconductor structure further includes a word line structure. The word line structure includes a floating gate formed on each of the active regions of the substrate, an inter-gate dielectric layer conformally covering the floating gate and the substrate, and a control gate formed over the floating gate and separated from the floating gate by the inter-gate dielectric layer. The word line structure has a plurality of protrusions correspondingly formed over the active regions.

The top surface of the isolation structures of the substrate is lower than the top surface of the floating gate of the word line structure, the width of each of the protrusions is less than or equal to the width of each of the active regions of the substrate.

The word line structure extends along a first direction, the active regions extend along a second direction, the first direction intersects the second direction, and the protrusions extend along the second direction and are aligned in the first direction.

In a cross-sectional view in the first direction, the word line structure has a crown shape, in a cross-sectional view in the second direction, the word line structure has a rectangular shape.

The spacing between the protrusions is greater than the top width of each of the isolation structures of the substrate, there is a liner layer between the substrate and the isolation structures.

The material of the liner layer includes silicon oxide, the inter-gate dielectric layer includes an oxide/nitride/oxide layer, the material of the floating gate and the control gate includes polycrystalline silicon.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

What is claimed is:

1. A method for forming a semiconductor structure, comprising:
providing a substrate, wherein the substrate comprises a plurality of active regions;
forming a first gate layer on the active regions of the substrate;
conformally forming an inter-gate dielectric layer on the substrate and the first gate layer, wherein the inter-gate dielectric layer forms a first opening between the first gate layer;
forming a second gate layer on the inter-gate dielectric layer, wherein the second gate layer is filled into the first opening;
forming a patterned photoresist layer on the second gate layer;
using the patterned photoresist layer as a mask and patterning the second gate layer to form a second opening, wherein the second opening is directly over the first opening; and
patterning the second gate layer, the inter-gate dielectric layer, and the first gate layer to form a word line structure on the substrate.

2. The method as claimed in claim 1, wherein:
the substrate comprises a plurality of isolation structures between the active regions,
a top surface of the isolation structures is higher than a top surface of the active regions and lower than a top surface of the first gate layer, and
a liner layer is between the substrate and the isolation structures.

3. The method as claimed in claim 1, wherein:
the word line structure has a plurality of protrusions correspondingly formed over the active regions, and
a width of each of the protrusions is less than or equal to a width of each of the active regions.

4. The method as claimed in claim 1, wherein a width of the second opening is greater than a width of the first opening.

5. The method as claimed in claim 1, wherein a depth of the first opening is greater than a depth of the second opening.

6. The method as claimed in claim 1, wherein the patterning of the second gate layer, the inter-gate dielectric layer, and the first gate layer form the word line structure further comprises:
forming a mask layer on the second gate layer, wherein the mask layer is filled into the second opening; and
performing an etching process to sequentially pattern the second gate layer, the inter-gate dielectric layer, and the first gate layer to form the word line structure.

7. The method as claimed in claim 6, wherein the etching process comprises an anisotropic etching process.

8. The method as claimed in claim 1, wherein the inter-gate dielectric layer comprises an oxide/nitride/oxide layer.

9. The method as claimed in claim 1, wherein a material of the first gate layer and the second gate layer comprises polycrystalline silicon.

10. A semiconductor structure, comprising:
a substrate, wherein the substrate comprises a plurality of active regions and a plurality of isolation structures disposed in an interleaving configuration, wherein a top surface of the isolation structures is higher than a top surface of the active regions; and
a word line structure, wherein the word line structure comprises:
a floating gate formed on each of the active regions of the substrate;
an inter-gate dielectric layer conformally covering the floating gate and the substrate; and
a control gate formed over the floating gate and separated from the floating gate by the inter-gate dielectric layer,
wherein the word line structure has a plurality of protrusions correspondingly formed over the active regions.

11. The semiconductor structure as claimed in claim 10, wherein a top surface of the isolation structures of the substrate is lower than a top surface of the floating gate of the word line structure.

12. The semiconductor structure as claimed in claim 10, wherein a width of each of the protrusions is less than or equal to a width of each of the active regions of the substrate.

13. The semiconductor structure as claimed in claim 10, wherein:
the word line structure extends along a first direction,
the active regions extend along a second direction,
the first direction intersects the second direction, and
the protrusions extend along the second direction and are aligned in the first direction.

14. The semiconductor structure as claimed in claim 13, wherein in a cross-sectional view in the first direction, the word line structure has a crown shape.

15. The semiconductor structure as claimed in claim 13, wherein in a cross-sectional view in the second direction, the word line structure has a rectangular shape.

16. The semiconductor structure as claimed in claim 10, wherein a spacing between the protrusions is greater than a top width of each of the isolation structures of the substrate.

17. The semiconductor structure as claimed in claim 10, wherein a liner layer is disposed between the substrate and the isolation structures.

18. The semiconductor structure as claimed in claim 10, wherein a material of the liner layer comprises silicon oxide.

19. The semiconductor structure as claimed in claim 10, wherein the inter-gate dielectric layer comprises an oxide/nitride/oxide layer.

20. The semiconductor structure as claimed in claim 10, wherein a material of the floating gate and the control gate comprises polycrystalline silicon.
